(19) United States
(12) Patent Application Publication
(10) Pub. No.: US 2020/0321503 A1
(43) Pub. Date: Oct. 8, 2020

(54) THERMOELECTRIC GENERATION DEVICE

(71) Applicant: KELK Ltd., Kanagawa (JP)

(72) Inventors: Toshihiko KISHIZAWA, Kanagawa (JP); Yoshitsugu KITSU, Kanagawa (JP); Shinichi FUJIMOTO, Kanagawa (JP)

(21) Appl. No.: 16/763,300

(22) PCT Filed: Nov. 22, 2018
(86) PCT No.: PCT/JP2018/043264

§ 371 Date: May 12, 2020

(30) Foreign Application Priority Data
Dec. 27, 2017 (JP) 2017-252643

(51) Int. Cl. H01L 35/04

(52) U.S. Cl. CPC H01L 35/04

(57) ABSTRACT

A thermoelectric generation device includes a thermoelectric generation module, a fan rotatable about a rotation axis and disposed on one side of the thermoelectric generation module in a first axis direction parallel to the rotation axis, a cover member which includes a facing plate disposed on one side of the fan in the first axis direction and facing the fan and a side plate disposed around the fan from the one side of the fan toward the other side thereof, a first intake port in the facing plate, a second intake port which is provided in the side plate and of which at least a portion is disposed on the one side with respect to the fan in the first axis direction, and an exhaust port in the side plate and disposed on the other side with respect to the fan in the first axis direction.

### FIELD

The present invention relates to a thermoelectric generation device.

### BACKGROUND

A thermoelectric generation device including a thermoelectric generation module which generates electric power using a Seebeck effect has been known. One end surface of the thermoelectric generation module is heated, the other end surface of the thermoelectric generation module is cooled, and thus, the thermoelectric generation module generates electric power.

### CITATION LIST

### Patent Literature

Patent Literature 1: JP 2015-171308 A

### SUMMARY

### Technical Problem

In a case where a fan is used to cool a thermoelectric generation module, if cooling efficiency of the fan decreases, power generation efficiency of a thermoelectric generation device decreases.

An object of an aspect of the present invention is to suppress a decrease in the cooling efficiency of the fan.

### Solution to Problem

According to an aspect of the present invention, a thermoelectric generation device comprises: a thermoelectric generation module; a fan which is rotatable about a rotation axis and is disposed on one side of the thermoelectric generation module in a first axis direction parallel to the rotation axis; a cover member which includes a facing plate which is disposed on one side of the fan in the first axis direction and faces the fan and a side plate which is disposed around the fan from the one side of the fan toward the other side thereof; a first intake port which is provided in the facing plate; a second intake port which is provided in the side plate and of which at least a portion is disposed on the one side with respect to the fan in the first axis direction; and an exhaust port which is provided in the side plate and is disposed on the other side with respect to the fan in the first axis direction.

### Advantageous Effects of Invention

According to an aspect of the present invention, a decrease in the cooling efficiency of the fan is suppressed.

### BRIEF DESCRIPTION OF DRAWINGS

FIG. 1 is a perspective view illustrating a thermoelectric generation device according to the present embodiment.

FIG. 2 is a cross-sectional view illustrating the thermoelectric generation device according to the present embodiment.

FIG. 3 is a perspective view schematically illustrating a thermoelectric generation module according to the present embodiment.

FIG. 4 is a view schematically illustrating the thermoelectric generation device according to the present embodiment.

FIG. 5 is a graph illustrating an experimental result on a cooling effect of the thermoelectric generation device according to the present embodiment.

FIG. 6 is an enlarged view of a portion of the thermoelectric generation device according to the present embodiment.

FIG. 7 is an enlarged view of a portion of the thermoelectric generation device according to the present embodiment.

FIG. 8 is a cross-sectional view illustrating the thermoelectric generation device according to the present embodiment.

### DESCRIPTION OF EMBODIMENTS

Hereinafter, an embodiment according to the present invention will be described with reference to the drawings, but the present invention is not limited thereto. Components of the embodiment described below can be appropriately combined. Moreover, some components may not be used.

In the following description, an XYZ orthogonal coordinate system is set, and a positional relationship of each portion will be described with reference to the XYZ orthogonal coordinate system. A direction parallel to an X axis in a predetermined plane is referred to as an X axis direction (second axis direction), a direction parallel to a Y axis orthogonal to the X axis in the predetermined plane is referred to as a Y axis direction (third axis direction), and a direction parallel to a Z axis orthogonal to the predetermined plane is referred to as a Z axis direction (first axis direction). The X axis direction, the Y axis direction, and the Z axis direction are orthogonal to each other. An XY plane including the X axis and the Y axis is parallel to the predetermined plane. A YZ plane including the Y axis and the Z axis is orthogonal to the XY plane. An XZ plane including the X axis and the Z axis is orthogonal to each of the XY plane and the YZ plane.

Moreover, in the following descriptions, one side in the Z axis direction is appropriately referred to as a +Z side, and the other side in the Z axis direction is appropriately referred to as a −Z side.

[Structure]

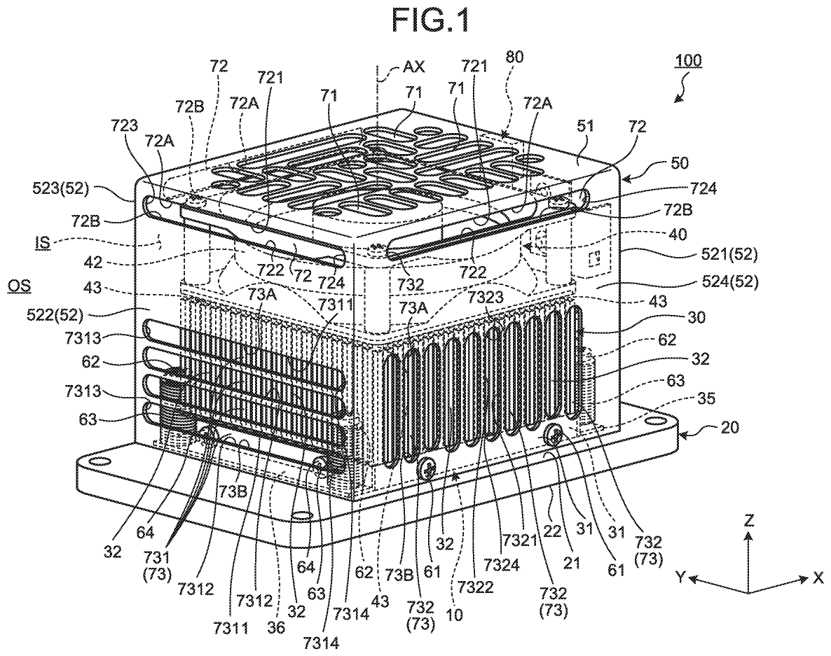

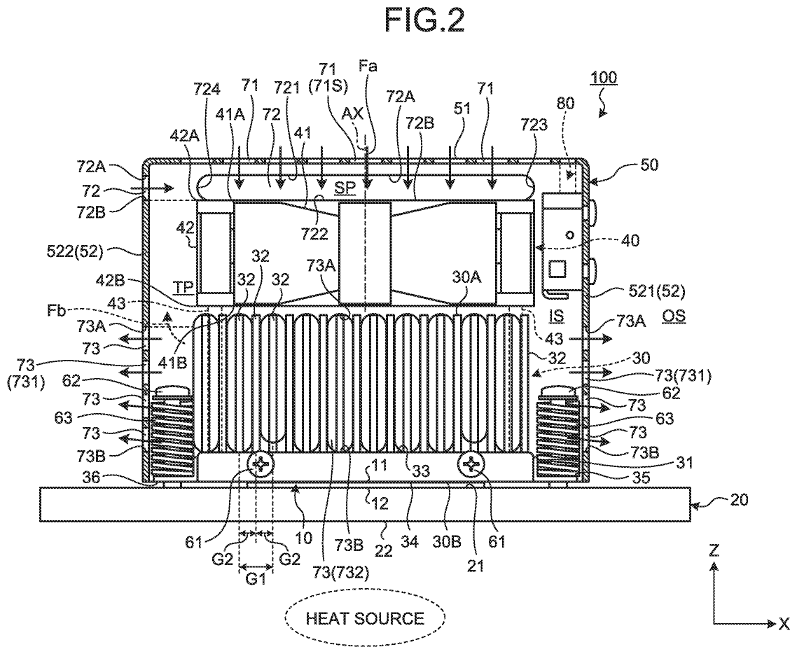

FIG. 1 is a perspective view illustrating a thermoelectric generation device 100 according to the present embodiment. FIG. 2 is a cross-sectional view illustrating the thermoelectric generation device 100 according to the present embodiment.

As illustrated in FIGS. 1 and 2, the thermoelectric generation device 100 includes a thermoelectric generation module 10, a heat receiving plate 20 which is connected to a −Z-side end surface 12 of the thermoelectric generation module 10, a heat sink 30 which has a heat radiating plate 31 connected to a +Z-side end surface 11 of the thermoelectric generation module 10, a fan unit 40 which includes a fan 41 which is rotatable about a rotation axis AX and is disposed on the +Z side of the thermoelectric generation module 10, and a cover member 50 which forms an internal space IS between the heat receiving plate 20 and the cover member 50.

<Thermoelectric Generation Module>

The thermoelectric generation module 10 generates electric power using a Seebeck effect. The −Z-side end surface 12 of the thermoelectric generation module 10 is heated, the +Z-side end surface 11 of the thermoelectric generation module 10 is cooled, and thus, the thermoelectric generation module 10 generates electric power.

The end surface 11 faces in the +Z direction. The end surface 12 faces in the −Z direction. Each of the end surfaces 11 and 12 is flat. Each of the end surfaces 11 and 12 is parallel to the XY plane. In the XY plane, an outer shape of the thermoelectric generation module 10 is substantially rectangular.

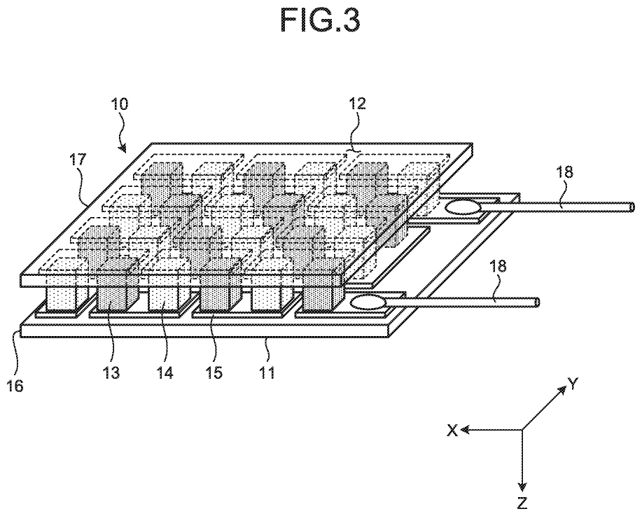

FIG. 3 is a perspective view schematically illustrating the thermoelectric generation module 10 according to the present embodiment. Moreover, in FIG. 3, the end surface 12 faces upward and the end surface 11 faces downward. The thermoelectric generation module 10 has a P-type thermoelectric semiconductor element 13, an N-type thermoelectric semiconductor element 14, an electrode 15, a first substrate 16, and a second substrate 17. The electrode 15 is connected to each of the P-type thermoelectric semiconductor element 13 and the N-type thermoelectric semiconductor element 14. The first substrate 16 is disposed on the +Z side of the P-type thermoelectric semiconductor element 13, the N-type thermoelectric semiconductor element 14, and the electrode 15. The second substrate 17 is disposed on the −Z side of the P-type thermoelectric semiconductor element 13, the N-type thermoelectric semiconductor element 14, and the electrode 15.

For example, each of the P-type thermoelectric semiconductor element 13 and the N-type thermoelectric semiconductor element 14 includes a BiTe-based thermoelectric material. Each of the first substrate 16 and the second substrate 17 is formed of an electrically insulating material such as ceramics or polyimide.

The first substrate 16 has the end surface 11. The second substrate 17 has the end surface 12. The second substrate 17 is heated, and the first substrate 16 is cooled. Accordingly, a temperature difference is provided between a +Z-side end and a −Z-side end of each of the P-type thermoelectric semiconductor element 13 and the N-type thermoelectric semiconductor element 14. When the temperature difference is provided between the +Z-side end and the −Z-side end of the P-type thermoelectric semiconductor element 13, in the P-type thermoelectric semiconductor element 13, holes move from the −Z-side end to the +Z-side end. When the temperature difference is provided between the +Z-side end and the −Z-side end of the N-type thermoelectric semiconductor element 14, in the N-type thermoelectric semiconductor element 14, electrons move from the −Z-side end to the +Z-side end. The P-type thermoelectric semiconductor element 13 and the N-type thermoelectric semiconductor element 14 are connected to each other via the electrode 15. A potential difference is generated between the electrodes 15 by the holes and the electrons. When the potential difference occurs between the electrodes 15, the thermoelectric generation module 10 generates electric power. A lead wire 18 is connected to the electrode 15. The thermoelectric generation module 10 outputs electric power via the lead wire 18.

<Heat Receiving Plate>

The heat receiving plate 20 receives heat from a heat source and transmits the heat to the thermoelectric generation module 10. The heat receiving plate 20 is formed of a metal material such as aluminum or copper. The heat receiving plate 20 is connected to the end surface 12 of the thermoelectric generation module 10.

The heat receiving plate 20 has a connection surface 21 which is connected to the end surface 12 of the thermoelectric generation module 10 and a heat receiving surface 22 which faces the heat source. Heat from the heat source is transmitted to the end surface 12 of the thermoelectric generation module 10 via the heat receiving plate 20.

The connection surface 21 faces in the +Z direction. The heat receiving surface 22 faces in the −Z direction. Each of the connection surface 21 and the heat receiving surface 22 is flat. Each of the connection surface 21 and the heat receiving surface 22 is parallel to the XY plane. In the XY plane, an outer shape of the heat receiving plate 20 is substantially rectangular. In the XY plane, the outer shape of the heat receiving plate 20 is larger than the outer shape of the thermoelectric generation module 10. The end surface 12 of the thermoelectric generation module 10 is connected to a central area of the connection surface 21.

<Heat Sink>

The heat sink 30 takes heat from the thermoelectric generation module 10. The heat sink 30 is formed of a metal material such as aluminum. The heat sink 30 is disposed between the thermoelectric generation module 10 and the fan 41 in the Z axis direction.

The heat sink 30 has a heat radiating plate 31 which is connected to the end surface 11 of the thermoelectric generation module 10 and fins 32 which are supported by the heat radiating plate 31. The fin 32 is a pin fin. Moreover, the fin 32 may be a plate fin.

The heat radiating plate 31 has a connection surface 34 which is connected to the end surface 11 of the thermoelectric generation module 10 and a support surface 33 which supports the fins 32. The fins 32 are connected to the support surface 33 of the heat radiating plate 31. The heat sink 30 takes heat from the end surface 11 of the thermoelectric generation module 10.

The support surface 33 faces in the +Z direction. The connection surface 34 faces in the −Z direction. The connection surface 34 is flat. Each of the support surface 33 and the connection surface 34 is parallel to the XY plane. In the XY plane, an outer shape of the heat radiating plate 31 is substantially rectangular. In the XY plane, the outer shape of the heat radiating plate 31 is larger than the outer shape of the thermoelectric generation module 10. The end surface 11 of the thermoelectric generation module 10 is connected to a central area of the connection surface 34.

Each of the fins 32 is long in the Z axis direction. A plurality of fins 32 are provided in each of the X axis direction and the Y axis direction. The fins 32 are disposed at regular intervals in each of the X axis direction and the Y axis direction. In the Z axis direction, each of the tips on the +Z side of the plurality of fins 32 is disposed at the same position.

<Fan Unit>

The fan unit 40 has the fan 41 which is rotatable about the rotation axis AX, a fan case 42 which is disposed around the fan 41, and an electric motor (not illustrated) which generates power for rotating the fan. The fan 41 operates to circulate air. The rotation axis AX of the fan 41 is parallel to the Z axis direction. The fan 41 is disposed on the +Z side of each of the thermoelectric generation module 10 and the heat sink 30.

The fan 41 is rotatably supported by the fan case 42. The fan case 42 is supported by the heat receiving plate 20 via a support member 43. The support member 43 is a rod-shaped member which is long in the Z axis direction.

The electric motor which rotates the fan 41 is operated by the electric power generated by the thermoelectric generation module 10. When the electric motor is operated, the fan 41 rotates. That is, the thermoelectric generation device 100 is a self-standing type thermoelectric generation device which operates the electric motor (electronic device) provided in the thermoelectric generation device 100 by the electric power generated by the thermoelectric generation module 10.

<Cover Member>

The cover member 50 protects the thermoelectric generation module 10, the heat sink 30, and the fan 41. Further, the cover member 50 suppresses a contact between a user (finger of user) of the thermoelectric generation device 100 and at least one of the fan 41 and the thermoelectric generation module 10. A −Z-side end of the cover member 50 faces the connection surface 21 of the heat receiving plate 20. The cover member 50 forms the internal space IS between the heat receiving plate 20 and the cover member 50. The thermoelectric generation module 10, the heat sink 30, and the fan unit 40 are disposed in the internal space IS.

The cover member 50 is disposed on the +Z side of the fan 41 and includes a facing plate 51 facing the fan 41, and a side plate 52 which is disposed around the thermoelectric generation module 10, the heat sink 30, and the fan unit 40. The side plate 52 is disposed around the fan 41 so as to surround the rotation axis AX of the fan 41 from the facing plate 51 toward the connection surface 21. A −Z-side end of the side plate 52 faces a peripheral edge region of the connection surface 21. The facing plate 51 is connected to a +Z-side end of the side plate 52.

The facing plate 51 has an outer surface facing an external space OS and an inner surface facing the internal space IS. The outer surface of the facing plate 51 faces in the +Z direction. The inner surface of the facing plate 51 faces in the −Z direction. Each of the outer surface and the inner surface of the facing plate 51 is flat. Each of the outer surface and the inner surface of the facing plate 51 is parallel to the XY plane. In the XY plane, an outer shape of the facing plate 51 is substantially rectangular.

The side plate 52 includes a first side plate 521 which is disposed on the +X side with respect to a center of the internal space IS, a second side plate 522 which is disposed on the −X side with respect to the center of the internal space IS, a third side plate 523 which is disposed on the +Y side with respect to the center of the internal space IS, and a fourth side plate 524 which is disposed on the −Y side with respect to the center of the internal space IS.

The first side plate 521 has an outer surface facing the external space OS and an inner surface facing the internal space IS. The outer surface of the first side plate 521 faces in the +X direction. The inner surface of the first side plate 521 faces in the −X direction. Each of the outer surface and the inner surface of the first side plate 521 is flat. Each of the outer surface and the inner surface of the first side plate 521 is parallel to the YZ plane. In the YZ plane, an outer shape of the first side plate 521 is substantially rectangular.

The second side plate 522 is disposed with a gap with respect to the first side plate 521 in the X axis direction. The second side plate 522 has an outer surface facing the external space OS and an inner surface facing the internal space IS. The outer surface of the second side plate 522 faces in the −X direction. The inner surface of the second side plate 522 faces the +X direction. Each of the outer surface and the inner surface of the second side plate 522 is flat. Each of the outer surface and the inner surface of the second side plate 522 is parallel to the YZ plane. In the YZ plane, an outer shape of the second side plate 522 is substantially rectangular.

The third side plate 523 is disposed between the first side plate 521 and the second side plate 522. The third side plate 523 has an outer surface facing the external space OS and an inner surface facing the internal space IS. The outer surface of the third side plate 523 faces in the +Y direction. The inner surface of the third side plate 523 faces in the −Y direction. Each of the outer surface and the inner surface of the third side plate 523 is flat. Each of the outer surface and the inner surface of the third side plate 523 is parallel to the XZ plane. In the XZ plane, an outer shape of the third side plate 523 is substantially rectangular.

The fourth side plate 524 is disposed between the first side plate 521 and the second side plate 522. The fourth side plate 524 is disposed with a gap with respect to the third side plate 523 in the Y axis direction. The fourth side plate 524 has an outer surface facing the external space OS and an inner surface facing the internal space IS. The outer surface of the fourth side plate 524 faces in the −Y direction. The inner surface of the fourth side plate 524 faces in the +Y direction. Each of the outer surface and the inner surface of the fourth side plate 524 is flat. Each of the outer surface and the inner surface of the fourth side plate 524 is parallel to the XZ plane. In the XZ plane, an outer shape of the fourth side plate 524 is substantially rectangular.

A peripheral edge portion of the facing plate 51, a +Z-side end of the first side plate 521, a +Z-side end of the second side plate 522, a +Z-side end of the third side plate 523, and a +Z-side end of the fourth side plate 524 are connected to each other. A +Y-side end of the first side plate 521 and a +X-side end of the third side plate 523 are connected to each other. A −Y-side end of the first side plate 521 and a +X-side end of the fourth side plate 524 are connected to each other. A +Y-side end of the second side plate 522 and a −X-side end of the third side plate 523 are connected to each other. A −Y-side end of the second side plate 522 and a −X-side end of the fourth side plate 524 are connected to each other.

<Fixed Structure>

The heat receiving plate 20 and the heat sink 30 are fixed to each other by screws 62. The heat receiving plate 20 and the fan unit 40 are fixed to each other via the support members 43. The heat sink 30 and the cover member 50 are fixed to each other by screws 61.

The side plate 52 is fixed to the heat radiating plate 31 by the screws 61. The screws 61 fix the third side plate 523 to a +Y-side side surface of the heat radiating plate 31. The screws 61 fix the fourth side plate 524 to a −Y-side side surface of the heat radiating plate 31.

The heat radiating plate 31 is fixed to the heat receiving plate 20 by the screws 62. A flange 35 is provided on a +X-side side surface of the heat radiating plate 31. A flange 36 is provided on a −X-side side surface of the heat radiating plate 31. Each of the flange 35 and the flange 36 is constituted by a portion of an angle material fixed to a side surface of the heat radiating plate 31. The angle material is an L-shaped member in the XZ plane. A portion of the angle material is fixed to each of the +X-side side surface and the −X-side side surface of the heat radiating plate 31 by screws 64. A portion of the angle material which is not in contact with the heat radiating plate 31 constitutes the flange 35 and the flange 36.

The flange 35 protrudes from the +X-side side surface of the heat radiating plate 31 in the +X direction. The flange 36 protrudes in the −X direction from the −X-side side surface of the heat radiating plate 31. Each of the flanges 35 and 36 and the connection surface 21 of the heat receiving plate 20 face each other.

The flange 35 is fixed to the heat receiving plate 20 by the screws 62. The flange 36 is fixed to the heat receiving plate 20 by the screws 62. The flanges 35 and 36 and the heat receiving plate 20 are fixed to each other by the screws 62, and thus, the heat radiating plate 31 is fixed to the heat receiving plate 20.

Two screws 62 for fixing the flange 35 and the heat receiving plate 20 to each other are disposed in the Y axis direction. Two screws 62 for fixing the flange 36 and the heat receiving plate 20 to each other are disposed in the Y axis direction. The heat radiating plate 31 is fixed to the heat receiving plate 20 by four screws 62.

Coil springs 63 are disposed between a head of the screw 62 and the flange 35 and between a head of the screw 62 and the flange 36, respectively. The screw 62 is screwed into the heat receiving plate 20 so that the coil spring 63 is contracted. Due to an elastic force of the coil spring 63, the thermoelectric generation module 10 can be interposed between the heat radiating plate 31 and the heat receiving plate 20 by a constant force. Moreover, a thermal deformation generated in at least one of the heat receiving plate 20 and the heat radiating plate 31 is absorbed by an elastic deformation of the coil spring 63. Thereby, it is possible to prevent an excessive force from acting on the thermoelectric generation module 10, a contact between the thermoelectric generation module 10 and at least one of the heat receiving plate 20 and the heat radiating plate 31 from being insufficient, and a force acting on the thermoelectric generation module 10 from being deviated.

In the XY plane, the screws 62 and the coil springs 63 are disposed between the first side plate 521 and the heat sink 30 and between the second side plate 522 and the heat sink 30. A distance W1 between the inner surface of the first side plate 521 and the heat sink 30 is substantially equal to a distance W2 between the inner surface of the second side plate 522 and the heat sink 30. A distance W3 between the inner surface of the third side plate 523 and the heat sink 30 is substantially equal to a distance W4 between the inner surface of the fourth side plate 524 and the heat sink 30. The distance W3 and the distance W4 are shorter than the distance W1 and the distance W2. That is, the third side plate 523 and the fourth side plate 524 are closer to the heat sink 30 than the first side plate 521 and the second side plate 522.

<First Intake Port>

The facing plate 51 has a first intake port 71. A plurality of first intake ports 71 are provided in the facing plate 51. Each of the first intake ports 71 includes a through hole penetrating the inner surface and the outer surface of the facing plate 51.

The first intake port 71 is disposed on the +Z side with respect to the fan 41. The first intake port 71 is provided at a position facing the fan 41. The first intake port 71 sucks air in the external space OS. When the fan 41 rotates, the air in the external space OS flows into the internal space IS via the first intake ports 71.

The plurality of first intake ports 71 are provided in each of the X axis direction and the Y axis direction. Each of the plurality of first intake ports 71 is a long hole elongated in the X axis direction or the Y axis direction. The first intake port 71 is defined by a pair of straight edges, an arc edge connecting one end of the pair of straight edges, and an arc edge connecting the other end of the pair of straight edges. The pair of straight edges are parallel to each other. Lengths and directions of the plurality of first intake ports 71 may be the same as each other or different from each other.

At least some of the plurality of first intake ports 71 may be circular.

<Second Intake Port>

The side plate 52 has a second intake port 72. A plurality of second intake ports 72 are provided in the side plate 52. Each of the second intake ports 72 includes a through hole penetrating the inner surface and the outer surface of the side plate 52.

In the Z axis direction, at least a portion of the second intake port 72 is disposed on the +Z side with respect to the fan 41. The second intake port 72 sucks the air in the external space OS. When the fan 41 rotates, the air in the external space OS flows into the internal space IS via the second intake ports 72.

The second intake port 72 is provided in at least one of the first side plate 521, the second side plate 522, the third side plate 523, and the fourth side plate 524. In the present embodiment, the second intake port 72 is provided in each of the second side plate 522, the third side plate 523, and the fourth side plate 524. The second intake port 72 may also be provided in the first side plate 521.

The second intake port 72 has a +Z-side end 72A and a −Z-side end 72B.

In a case where only one second intake port 72 is provided in the Z axis direction, the +Z-side end 72A of the second intake port 72 refers to the most +Z-side portion of one second intake port 72. In a case where only one second intake port 72 is provided in the Z axis direction, the −Z-side end 72B of the second intake port 72 refers to the most −Z-side portion of the one second intake port 72.

In a case where the plurality of second intake ports 72 are provided in the Z axis direction, the +Z-side end 72A of the second intake port 72 refers to the most +Z-side portion of the second intake port 72 disposed on the most +Z side of the plurality of second intake ports 72. In a case where the plurality of second intake ports 72 are provided in the Z axis direction, the −Z-side end 72B of the second intake port 72 refers to the most −Z-side portion of the second intake port 72 disposed on the most −Z side of the plurality of second intake ports 72.

The fan 41 has a +Z-side end 41A and a −Z-side end 41B.

The +Z-side end 41A of the fan 41 refers to the most +Z-side portion of the fan 41. The −Z-side end 41B of the fan 41 refers to the most −Z-side portion of the fan 41.

In the Z axis direction, the +Z-side end 72A of the second intake port 72 is disposed on the +Z side with respect to the +Z-side end 41A of the fan 41. In the Z axis direction, the −Z-side end 72B of the second intake port 72 is disposed at the same position as that of the +Z-side end 41A of the fan 41.

In the Z axis direction, the +Z-side end 41A of the fan 41 is disposed at the same position as that of a +Z-side end 42A of the fan case 42. In the Z axis direction, the −Z-side end 41B of the fan 41 is disposed at the same position as that of a −Z-side end 42B of the fan case 42. Moreover, in the Z axis direction, the position of the end 41A may be different from the position of the end 42A, or the position of the end 41B may be different from the position of the end 42B.

In the direction parallel to the XY plane, a size of the second intake port 72 is larger than a size (diameter) of the fan 41. In the direction parallel to the XY plane, the size of the second intake port 72 is equal to or larger than a size of the heat sink 30. In the present embodiment, the size of the second intake port 72 is substantially the same as the size of the heat sink 30.

The second intake port 72 provided in the second side plate 522 is a long hole elongated in the Y axis direction. In the Y axis direction, a size of the second intake port 72 provided in the second side plate 522 is larger than the size of the fan 41 and is equal to or larger than the size of the heat sink 30. In the present embodiment, the size of the second intake port 72 is substantially the same as the size of the heat sink 30.

The second intake port 72 provided in each of the third side plate 523 and the fourth side plate 524 is a long hole elongated in the X axis direction. In the X axis direction, a size of the second intake port 72 provided in each of the third side plate 523 and the fourth side plate 524 is larger than the size of the fan 41 and is equal to or larger than the size of the heat sink 30. In the present embodiment, the size of the second intake port 72 is substantially the same as the size of the heat sink 30.

In the present embodiment, only one second intake port 72 is provided in each of the second side plate 522, the third side plate 523, and the fourth side plate 524 in the Z axis direction.

The second intake port 72 is defined by a straight edge 721, a straight edge 722 which is located on the −Z side with respect to the straight edge 721, an arc edge 723 which connects one end of the straight edge 721 and one end of the straight edge 722 to each other, and an arc edge 724 which connects the other end of the straight edge 721 and the other end of the straight edge 722 to each other. The straight edge 721 and the straight edge 722 are parallel to each other. Each of the straight edge 721 and the straight edge 722 is parallel to the XY plane.

In the present embodiment, the end 72A includes the straight edge 721. The end 72B includes the straight edge 722.

A plurality of second intake ports 72 may be provided in the Z axis direction. Further, the plurality of second intake ports 72 may be provided in the second side plate 522 in the Y axis direction. The plurality of second intake ports 72 may be provided in each of the third side plate 523 and the fourth side plate 524 in the X axis direction.

<Exhaust Port>

The side plate 52 has an exhaust port 73. A plurality of exhaust ports 73 are provided in the side plate 52. Each of the exhaust ports 73 includes a through hole penetrating the inner surface and the outer surface of the side plate 52.

In the Z axis direction, the exhaust port 73 is disposed on the −Z side with respect to the first intake port 71 and the second intake port 72. In the Z axis direction, the exhaust port 73 is disposed on the −Z side with respect to the fan 41. When the fan 41 rotates, at least a portion of the air in the internal space IS flows out to the external space OS via the exhaust ports 73.

The exhaust port 73 is provided in at least one of the first side plate 521, the second side plate 522, the third side plate 523, and the fourth side plate 524. In the present embodiment, the exhaust port 73 is provided in each of the first side plate 521, the second side plate 522, the third side plate 523, and the fourth side plate 524.

The exhaust port 73 has a +Z-side end 73A and a −Z-side end 73B.

In a case where only one exhaust port 73 is provided in the Z axis direction, the +Z-side end 73A of the exhaust port 73 refers to the most +Z-side portion of the one exhaust port 73. In the case where only one exhaust port 73 is provided in the Z axis direction, the −Z-side end 73B of the exhaust port 73 refers to the most −Z-side portion of one exhaust port 73.

In the case where the plurality of exhaust ports 73 are provided in the Z axis direction, the +Z-side end 73A of the exhaust ports 73 refers to the most +Z-side portion of the exhaust port 73 disposed on the most +Z side of the plurality of exhaust ports 73. In the case where the plurality of exhaust ports 73 are provided in the Z axis direction, the −Z-side end 73B of the exhaust ports 73 refers to the most −Z-side portion of the exhaust port 73 disposed on the most −Z side of the plurality of exhaust ports 73.

The heat sink 30 has a +Z-side end 30A and a −Z-side end 30B.

The +Z-side end 30A of the heat sink 30 refers to the most +Z-side portion of the heat sink 30. The −Z-side end 30B of the heat sink 30 refers to the most −Z-side portion of the heat sink 30.

In the present embodiment, the +Z-side end 30A of the heat sink 30 includes a +Z-side tip of the fin 32. The −Z-side end 30B of the heat sink 30 includes the connection surface 34 of the heat radiating plate 31.

As illustrated in FIG. 2, the +Z-side end 73A of the exhaust port 73 is disposed on the −Z side from the +Z-side end 30A of the heat sink 30 in the Z axis direction.

Further, the −Z-side end 73B of the exhaust port 73 is disposed on the −Z side from the support surface 33 of the heat radiating plate 31 in the Z axis direction.

In the present embodiment, the exhaust port 73 includes a first exhaust port 731 which is provided in each of the first side plate 521 and the second side plate 522 and is long in the Y axis direction, and a second exhaust port 732 which is provided in each of the third side plate 523 and the fourth side plate 524 and is long in the Z axis direction.

The first exhaust port 731 provided in each of the first side plate 521 and the second side plate 522 is a long hole elongated in the Y axis direction. In the Y axis direction, a size of the first exhaust port 731 is larger than the size of the fan 41, and is substantially the same as the size of the heat sink 30.

A plurality of first exhaust ports 731 are provided in each of the first side plate 521 and the second side plate 522 in the Z axis direction.

The first exhaust port 731 is defined by a straight edge 7311, a straight edge 7312 which is located on the −Z side with respect to the straight edge 7311, an arc edge 7313 which connects one end of the straight edge 7311 and one end of the straight edge 7312 to each other, and an arc edge 7314 which connects the other end of the straight edge 7311 and the other end of the straight edge 7312 to each other. The straight edge 7311 and the straight edge 7312 are parallel to each other. Each of the straight edge 7311 and the straight edge 7312 is parallel to the XY plane.

In the present embodiment, the end 73A includes the straight edge 7311 of the first exhaust port 731 disposed on the most +Z side among the plurality of first exhaust ports 731 disposed in the Z axis direction. The end 73B includes the straight edge 7312 of the first exhaust port 731 disposed on the most −Z side among the plurality of first exhaust ports 731 disposed in the Z axis direction.

Only one first exhaust port 731 may be provided in the Z axis direction. The plurality of first exhaust ports 731 may be provided in the Y axis direction.

The second exhaust port 732 provided in each of the third side plate 523 and the fourth side plate 524 is a long hole elongated in the Z axis direction. In the Z axis direction, the size of the second exhaust port 732 is smaller than the size of the heat sink 30.

A plurality of second exhaust ports 732 are provided in each of the third side plate 523 and the fourth side plate 524 in the X axis direction.

The second exhaust port 732 is defined by a straight edge 7321, a straight edge 7322 which is located on the −X side with respect to the straight edge 7321, an arc edge 7323 which connects a +Z-side end of the straight edge 7321 and a +Z-side end of the straight edge 7322 to each other, and an arc edge 7324 which connects a −Z-side end of the straight edge 7321 and a −Z-side end of the straight edge 7322 to each other. The straight edge 7321 and the straight edge 7322 are parallel to each other. Each of the straight edge 7321 and the straight edge 7322 is parallel to the Z axis.

In the present embodiment, the end 73A includes the arc edge 7323. The end 73B includes the arc edge 7324.

The plurality of first exhaust ports 731 may be provided in the Z axis direction.

As illustrated in FIG. 2, the fins 32 are disposed at a regular interval G2 in each of the X axis direction and the Y axis direction. The second exhaust ports 732 provided in each of the third side plate 523 and the fourth side plate 524 are disposed at a regular interval G1 in the X axis direction. In the X axis direction, a size of the second exhaust port 732 is equal to or smaller than a size of the fin 32. In the X axis direction, a position of the second exhaust port 732 coincides with a position of a space between the adjacent fins 32. That is, in the X axis direction, a center line of the side plate 52 between the adjacent second exhaust ports 732 coincides with a center line of the fin 32. The interval G1 between the second exhaust ports 732 adjacent in the X axis direction is an integral multiple of the interval G2 between the fins 32 adjacent in the X axis direction. In the present embodiment, the interval G1 between the second exhaust ports 732 adjacent in the X axis direction is two times the interval G2 between the fins 32 adjacent in the X axis direction. In the X axis direction, the position of the center of the second exhaust port 732 coincides with the position of the center of the fin 32.

The interval G1 between the second exhaust ports 732 may be any integer multiple of three times or more the interval G2 between the fins 32. The interval G1 between the second exhaust ports 732 may be the same as the interval G2 between the fins 32.

<Width of Long Hole>

As described above, each of the first intake port 71, the second intake port 72, and the exhaust port 73 is a long hole. For example, a width of the long hole is 10 [mm] or less. Thereby, for example, a finger of the user is prevented from passing through the long hole, and a contact between the finger of the user, and at least one of the fan 41 and the thermoelectric generation module 10 is suppressed. The cover member 50 functions as a so-called finger guard.

<Space>

The inner surface of the facing plate 51 and the +Z-side end surface of the fan unit 40 face each other via a gap. A first space SP is formed between the inner surface of the facing plate 51 and the fan 41. Each of the first intake ports 71 and the second intake ports 72 faces the first space SP. At least a portion of the air sucked from the first intake ports 71 and the second intake ports 72 flows into the first space SP.

In the present embodiment, at least one first intake port 71S among the plurality of first intake ports 71 is provided at a position coinciding with the rotation axis AX in the XY plane. Since the first space SP is formed between the facing plate 51 and the fan unit 40, when the fan 41 rotates, a sufficient amount of air flows into the first space SP not only from the first intake ports 71 provided at the positions different from the rotation axis AX in the XY plane, but also, as illustrated by an arrow Fa, from the first intake port 71S provided at the position coinciding with the rotation axis AX in the XY plane.

Moreover, the inner surface of the side plate 52 faces the fan 41 (fan unit 40) and the heat sink 30 via a gap. A second space TP is formed between the inner surface of the side plate 52 and the fan 41 and between the inner surface of the side plate 52 and the heat sink 30. The second intake ports 72 face the second space TP. The second intake ports 72 are closer to the second space TP than the first intake ports 71. At least a portion of the air supplied from the second intake ports 72 flows into the second space TP.

<Connector>

The thermoelectric generation device 100 includes a connector 80 which can be connected to an external electric device. For example, the connector 80 includes a Universal Serial Bus (USB) connector. A portion of the electric power generated by the thermoelectric generation module 10 is supplied to the electric motor which rotates the fan 41. A portion of the electric power generated by the thermoelectric generation module 10 is supplied to the electric device connected to the connector 80.

[Operation]

Next, an example of the operation of the thermoelectric generation device 100 according to the present embodiment will be described. When the heat receiving plate 20 of the thermoelectric generation device 100 is heated by the heat source, the end surface 12 of the thermoelectric generation module 10 in contact with the heat receiving plate 20 is heated, and the thermoelectric generation module 10 generates electric power. At least a portion of the electric power generated by the thermoelectric generation module 10 is supplied to the electric motor for rotating the fan 41. The electric motor is operated by electric power supplied from the thermoelectric generation module 10. The fan 41 is rotated by the operation of the electric motor.

When the fan 41 rotates, air in the external space OS is sucked into the first intake ports 71 and the second intake ports 72, respectively. The air in the external space OS flows into the internal space IS via each of the first intake ports 71 and the second intake ports 72.

At least a portion of the air which has flowed into the internal space IS and has passed through the fan 41 is supplied to the heat sink 30. The air supplied from the fan 41 to the heat sink 30 comes into contact with the surface of the fin 32 and the surface of the heat sink 30 including the support surface 33 of the heat radiating plate 31. The air in contact with the surface of the heat sink 30 takes heat from the heat sink 30. By taking the heat from the heat sink 30, the end surface 11 of the thermoelectric generation module 10 which is in contact with the heat sink 30 is cooled. Accordingly, a sufficient temperature difference is provided between the end surface 11 and the end surface 12 of the thermoelectric generation module 10. Since the sufficient temperature difference is provided between the end surface 11 and the end surface 12, the thermoelectric generation module 10 can efficiently generate electric power.

The air of which a temperature increases by taking the heat from the heat sink 30 flows out from the exhaust ports 73 to the external space OS. The air flowing out from the exhaust ports 73 to the external space OS flows in the direction parallel to the XY plane. That is, the air flowing out from the exhaust ports 73 flows away from the cover member 50. Therefore, a high-temperature air flowing out from the exhaust ports 73 is prevented from flowing into the internal space IS again via the first intake ports 71 and the second intake ports 72.

In the present embodiment, the first intake ports 71 and the second intake ports 72 exist at positions far from the heat receiving plate 20 (heat source). Therefore, the temperature of the air in the external space OS near the first intake ports 71 and the second intake ports 72 is lower than the temperature of the air in the external space OS near the heat receiving plate 20. When the fan 41 rotates, a low-temperature air flows into the internal space IS via the first intake ports 71 and the second intake ports 72. The air which has flowed into the internal space IS comes into contact with the surface of the heat sink 30 and takes heat from the heat sink 30. The air of which the temperature increases by taking the heat from the heat sink 30 flows out to the external space OS from the exhaust ports 73 located closer to the heat receiving plate 20 (heat source) than the first intake ports 71 and the second intake ports 72.

In the present embodiment, at least a portion of the air which has flowed into the internal space IS via the first intake ports 71 and the second intake ports 72 flows into the first space SP between the facing plate 51 and the fan unit 40. When the air flows into the first space SP, a pressure in the first space SP increases. Further, at least a portion of the air which has flowed into the internal space IS via the first intake ports 71 and the second intake ports 72 flows into the second space TP between the inner surface of the side plate 52, and the fan unit 40 and the heat sink 30. The air which has flowed into the second space TP flows in the −Z direction in the second space TP. At least a portion of the low-temperature air which has flowed into the internal space IS via the first intake port 71 and the second intake port 72 flows in the −Z direction in the second space TP. Accordingly, the air which comes into contact with the surface of the heat sink 30 and of which the temperature increases is prevented from flowing in the +Z direction in the second space TP.

That is, the air which comes into contact with the surface of the heat sink 30 and of which the temperature increases tends to flow in the +Z direction in the second space TP as indicated by an arrow Fb in FIG. 2. In the present embodiment, at least a portion of the low-temperature air which has flowed into the internal space IS via the first intake ports 71 and the second intake ports 72 flows in the −Z direction in the second space TP. Therefore, the high-temperature air in contact with the surface of the heat sink 30 is prevented from flowing in the +Z direction in the second space TP. Accordingly, the high-temperature air in contact with the surface of the heat sink 30 is prevented from being sucked into the fan 41 again. The air which comes into contact with the surface of the heat sink 30 and of which the temperature increases is smoothly discharged to the external space OS via the exhaust port 73. The low-temperature air which has flowed into the internal space IS from the external space OS via the first intake ports 71 and the second intake ports 72 is sucked into the fan 41, and the high-temperature air in contact with the surface of the heat sink 30 is prevented from being sucked into the fan 41. Accordingly, a low-temperature air is supplied from the fan 41 to the heat sink 30. Therefore, the heat sink 30 is sufficiently cooled, and a decrease in cooling efficiency of the fan 41 is suppressed. Since the heat sink 30 is sufficiently cooled, a sufficient temperature difference is provided between the end surface 11 and the end surface 12 of the thermoelectric generation module 10. Since the sufficient temperature difference is provided between the end surface 11 and the end surface 12, the thermoelectric generation module 10 can efficiently generate electric power.

In the present embodiment, the +Z-side end 73A of the exhaust port 73 is disposed on the −Z side with respect to the +Z-side end 30A (the tip of the fin 32) of the heat sink 30. Thus, the air supplied to the fins 32 from the fan 41 comes into sufficient contact with the surface of the fin 32, and thereafter, can flow out to the external space OS via the exhaust ports 73.

Moreover, in the present embodiment, the −Z-side end 73B of the exhaust port 73 is disposed on the −Z side with respect to the support surface 33 of the heat radiating plate 31. Accordingly, the air supplied from the fan 41 to the fins 32 flows to the −Z-side end of the fins 32, comes into sufficient contact with the surface of the fins 32, and further comes into sufficient contact with the support surface 33 of the heat radiating plate 31. After that, the air can flow out to the external space OS via the exhaust ports 73.

Moreover, in the present embodiment, the interval G1 between the second exhaust ports 732 adjacent in the X axis direction is an integral multiple of the interval G2 between the fins 32 adjacent in the X axis direction. Accordingly, the air which flows into the internal space IS from the first intake ports 71 and the second intake ports 72 by the rotation of the fan 41 and is supplied to the heat sink 30 flows between the adjacent fins 32, and thereafter, smoothly flows out from the second exhaust ports 732.

Each of the first exhaust ports 731 is long in the Y axis direction. Accordingly, a total area of the first exhaust ports 731 can increase. Therefore, the air in the internal space IS is smoothly discharged via the first exhaust ports 731.

### Usage Example

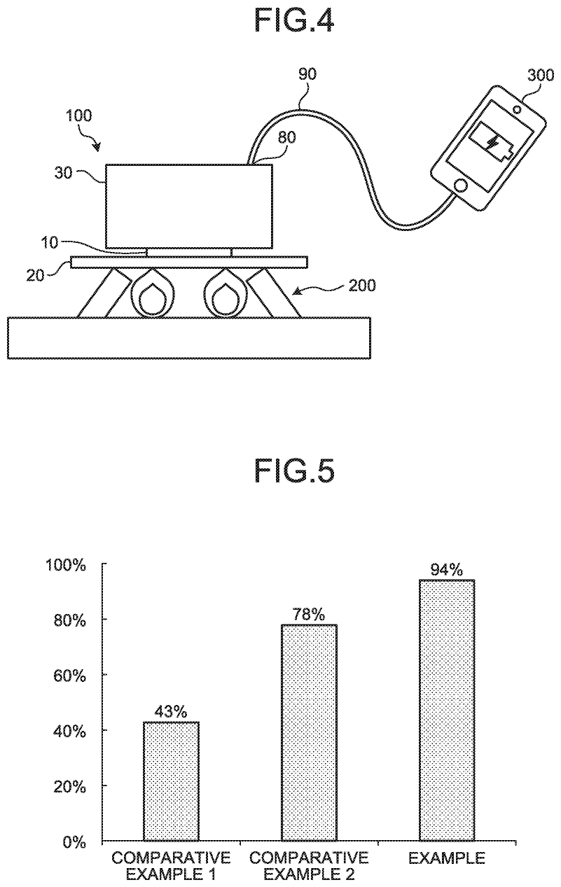

FIG. 4 is a view illustrating a usage example of the thermoelectric generation device 100 according to the present embodiment. The thermoelectric generation device 100 is installed on a cassette stove 200. The cassette stove 200 is a heat source of the thermoelectric generation device 100. When the heat receiving plate 20 of the thermoelectric generation device 100 is heated by the cassette stove 200, the thermoelectric generation device 100 generates electric power. In the example illustrated in FIG. 4, the connector 80 of the thermoelectric generation device 100 and an electric device 300 are connected by a cable 90. For example, the cable 90 is a USB cable. In the example illustrated in FIG. 4, the electric device 300 is a mobile device such as a smartphone or a tablet computer. The thermoelectric generation device 100 can function as a charger for the electric device 300. For example, in an emergency or outdoor activity, the electric device 300 can be charged using the thermoelectric generation device 100 and the cassette stove 200.

Moreover, the heat source is not limited to the cassette stove 200. An example of the heat source includes a fireplace stove, a bonfire, a charcoal fire, and waste heat from industrial equipment. Moreover, the electric device 300 which uses the electric power from the thermoelectric generation device 100 is not limited to a mobile device. An example of the electric device which uses the electric power from the thermoelectric generation device 100 includes a fan, a radio, a humidifier, and a thermo-hygrometer. The electric device such as a fan, a radio, a humidifier, and a thermo-hygrometer is operated by the electric power supplied from the thermoelectric generation device 100. Thus, even in a situation where wiring and power supply are difficult, electric power can be obtained by securing the thermoelectric generation device 100 and the heat source.

[Effect]

As described above, according to the present embodiment, the first intake ports 71 are provided in the facing plate 51, and the second intake ports 72 are provided in the side plate 52. Thereby, a total area of the intake ports increases. Therefore, the low-temperature air in the external space OS sufficiently flows into the internal space IS. When the low-temperature air sufficiently flows into the internal space IS from the external space OS, a decrease in cooling efficiency of the fan 41 is suppressed, and the end surface 11 of the thermoelectric generation module 10 is sufficiently cooled. Accordingly, a sufficient temperature difference is provided between the end surface 11 and the end surface 12 of the thermoelectric generation module 10. Since the sufficient temperature difference is provided between the end surface 11 and the end surface 12, a decrease in power generation efficiency of the thermoelectric generation module 10 is suppressed.

As described above, the cover member 50 functions as a finger guard which suppresses the contact between the finger of the user of the thermoelectric generation device 100 and the fan 41 or the thermoelectric generation module 10. Therefore, a width size of the first intake port 71 is limited. That is, it is necessary to reduce the width of the first intake port 71 so that the finger of the user does not pass through the first intake port 71. When the width of the first intake port 71 decreases, a flow path resistance of the air passing through the first intake port 71 increases. Further, even if the plurality of first intake ports 71 are provided in the facing plate 51, it is difficult to sufficiently increase the total area of the first intake ports 71. Therefore, merely providing the first intake ports 71 in the facing plate 51 may make it difficult to allow low-temperature air to sufficiently flow into the internal space IS.

Further, since the facing plate 51 and the fan 41 face each other, the fan 41 is an obstacle to the air flowing into the internal space IS via the first intake ports 71. Therefore, a pressure loss of the air which has flowed into the internal space IS via the first intake port 71 increases, and there is a possibility that the air is not sufficiently supplied to the heat sink 30 existing on the −Z side of the fan 41. As a result, the cooling efficiency of the heat sink 30 may be reduced.

In the present embodiment, the second intake ports 72 are provided in the side plate 52. Therefore, the low-temperature air in the external space OS sufficiently flows into the internal space IS via both the first intake ports 71 and the second intake ports 72. Therefore, a decrease in the cooling efficiency of the fan 41 is suppressed.

In the present embodiment, the first space SP is formed between the facing plate 51 and the fan 41. Accordingly, the pressure of the first space SP is increased by the air flowing into the internal space IS from the first intake ports 71 and the second intake ports 72. Therefore, the air which comes into contact with the surface of the heat sink 30 and of which the temperature increases is prevented from flowing in the +Z direction in the second space TP. Therefore, it is possible to prevent the air which comes into contact with the surface of the heat sink 30 and of which the temperature increases from being sucked into the fan 41 again. The low-temperature air which has flowed into the internal space IS from the external space OS via the first intake ports 71 and the second intake ports 72 is sucked into the fan 41, and the air which comes into contact with the surface of the heat sink 30 and of which the temperature increases is prevented from being sucked into the fan 41. Therefore, low-temperature air is supplied from the fan 41 to the heat sink 30. Therefore, the heat sink 30 is sufficiently cooled, and a decrease in cooling efficiency of the fan 41 is suppressed.

FIG. 5 is a graph illustrating an experimental result on a cooling effect of the thermoelectric generation device 100 according to the present embodiment. In the experiment, a thermoelectric generation device (Reference Example) which does not have a cover member and a thermoelectric generation device (Comparative Example 1, Comparative Example 2, and Example) which has a cover member were prepared, and when the heat receiving plate was heated under the same conditions, amounts of power generation output from each thermoelectric generation device were measured. In the thermoelectric generation device according to Reference Example which does not have the cover member, low-temperature air is sufficiently supplied to the heat sink 30 by the rotation of the fan 41. The low-temperature air is sufficiently supplied to the heat sink 30 and the end surface 11 of the thermoelectric generation module 10 is sufficiently cooled, and thus, a sufficient temperature difference is provided between the end surface 11 and the end surface 12 of the thermoelectric generation module 10. Therefore, the amount of power generation output from the thermoelectric generation module 10 is large.

The cover member of the thermoelectric generation device according to Comparative Example 1 has the first intake ports 71 and does not have the second intake ports 72. In the thermoelectric generation device according to Comparative Example 1, the first space SP between the facing plate 51 and the fan 41 is small. Since the facing plate 51 and the fan 41 are close to each other, an inflow of air from the first intake port 71S provided at the position coinciding with the rotation axis AX in the XY plane among the plurality of first intake ports 71 into the internal space IS is severely restricted.

The cover member of the thermoelectric generation device according to Comparative Example 2 has the first intake ports 71 and does not have the second intake ports 72. In the thermoelectric generation device according to Comparative Example 2, the first space SP between the facing plate 51 and the fan 41 is large. Since the first space SP is large, the restriction of the inflow of air from the first intake port 71S provided at the position coinciding with the rotation axis AX in the XY plane among the plurality of first intake ports 71 into the internal space IS is small. However, a total opening area is not sufficient.

The cover member of the thermoelectric generation device 100 according to Example has the first intake ports 71 and the second intake ports 72 as described in the embodiment. Moreover, in the thermoelectric generation device 100 according to Example, the first space SP between the facing plate 51 and the fan 41 is large. Low-temperature air is sufficiently supplied to the internal space IS via the first intake ports 71 and the second intake ports 72. Moreover, since the air which has flowed into the internal space IS from the second intake ports 72 flows in a direction parallel to the XY plane, an air curtain effect is obtained, which prevents the air which comes into contact with the heat sink 30 and of which the temperature increases from flowing into the fan 41.

In FIG. 5, a vertical axis indicates a proportion of an amount of power generation output from the thermoelectric generation device according to each of Comparative Example 1, Comparative Example 2, and Example, when the amount of power generation output from the thermoelectric generation device according to Reference Example is 100%.

As illustrated in FIG. 5, the amount of power generation output from the thermoelectric generation device according to Comparative Example 1 is 43[%] of the amount of power generation output from the thermoelectric generation device according to Reference Example. In the thermoelectric generation device according to Comparative Example 1, the second intake ports 72 do not exist, and air flows into the internal space IS only from the first intake ports 71. Therefore, even if the fan 41 rotates, it is difficult for sufficient air to flow into the internal space IS from the external space OS. In addition, the first space SP is small, and it is difficult for the air which has flowed into the internal space IS via the first intake ports 71 to flow through the second space TP in the −Z direction. Accordingly, there is a high possibility that the air which comes into contact with the surface of the heat sink 30 and of which the temperature increases flows through the second space TP in the +Z direction and is sucked into the fan 41 again. Therefore, the end surface 11 of the thermoelectric generation module 10 is not sufficiently cooled. As a result, the temperature difference between the end surface 11 and the end surface 12 of the thermoelectric generation module 10 is small, and the amount of power generation output from the thermoelectric generation module 10 is small.

The amount of power generation output from the thermoelectric generation device according to Comparative Example 2 is 78[%] of the amount of power generation output from the thermoelectric generation device according to Reference Example. In the thermoelectric generation device according to Comparative Example 2, although the second intake ports 72 do not exist, the sufficient first space SP exists. Accordingly, the air which has flowed into the internal space IS via the first intake port 71 can flow through the second space TP in the −Z direction. Therefore, the air which comes into contact with the surface of the heat sink 30 and of which the temperature increases is prevented from flowing through the second space TP in the +Z direction and being sucked into the fan 41 again. Therefore, compared to the thermoelectric generation device according to Comparative Example 1, in the thermoelectric generation device according to Comparative Example 2, the end surface 11 of the thermoelectric generation module 10 is cooled, and thus, the temperature difference between the end surface 11 and the end surface 12 of the thermoelectric generation module 10 is larger than the temperature difference according to Comparative Example 1. As a result, the amount of power generation output from the thermoelectric generation module 10 is large.

The amount of power generation output from the thermoelectric generation device 100 according to Example is 94[%] of the amount of power generation output from the thermoelectric generation device 100 according to Reference Example. In the thermoelectric generation device 100 according to Example, low-temperature air is sufficiently supplied to the internal space IS via both the first intake ports 71 and the second intake ports 72. Further, since there is a sufficient first space SP, the air which has flowed into the internal space IS via the first intake ports 71 and the second intake ports 72 can flow through the second space TP in the −Z direction. Therefore, the air which comes into contact with the surface of the heat sink 30 and of which the temperature increases is prevented from flowing through the second space TP in the +Z direction and being sucked into the fan 41 again. Therefore, compared to the thermoelectric generation devices according to Comparative Example 1 and Comparative Example 2, in the thermoelectric generation device 100 according to Example, the end surface 11 of the thermoelectric generation module 10 is sufficiently cooled, and thus, the temperature difference between the end surface 11 and the end surface 12 of the thermoelectric generation module 10 is larger than the temperature differences according to Comparative Example 1 and Comparative Example 2. As a result, the amount of power generation output from the thermoelectric generation module 10 is large.

When a pressure of the first space SP according to Example is represented by P, a pressure of the first space SP according to Comparative Example 1 is represented by P1, a pressure of the first space SP according to Comparative Example 2 is represented by P2, and a pressure between the exhaust port 73 and the side plate 52 is represented by Ps, a relationship of “P1<P2<P<Ps” is satisfied. Accordingly, in the present embodiment, the air which comes into contact with the surface of the heat sink 30 and of which the temperature increases is prevented from being sucked into the fan 41. Further, in the present embodiment, since the flows of air in the first space SP and the second space TP function as an air curtain, the air of which the temperature increases is more effectively prevented from being sucked into the fan 41.

### Other Embodiments

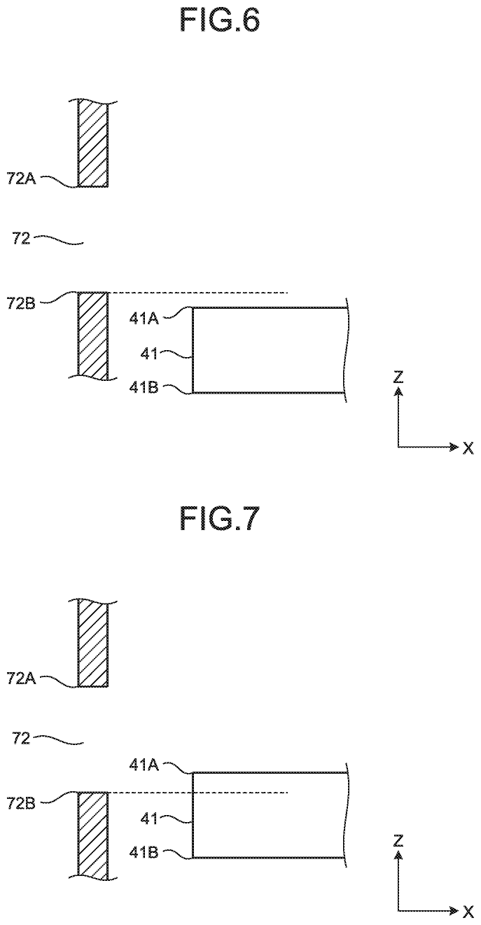

Each of FIGS. 6 and 7 is an enlarged view of a portion of the thermoelectric generation device 100 according to the present embodiment. In the above-described embodiment, the −Z-side end 72B of the second intake port 72 is located at the same position as that of the +Z-side end 41A of the fan 41 in the Z axis direction. As illustrated in FIG. 6, the −Z-side end 72B of the second intake port 72 may be disposed on the +Z side with respect to +Z-side end 41A of the fan 41 in the Z axis direction. Further, as illustrated in FIG. 7, the −Z-side end 72B of the second intake port 72 may be disposed on the −Z side with respect to the +Z-side end 41A of the fan 41 in the Z axis direction.

That is, the +Z-side end 72A of the second intake port 72 may be disposed on the +Z side with respect to the +Z-side end 41A of the fan 41 in the Z axis direction. The +Z-side end 72A of the second intake port 72 is disposed on the +Z side with respect to the +Z-side end 41A of the fan 41 in the Z axis direction, and thus, as described in the embodiment, it is possible to suppress the decrease in cooling efficiency of the fan 41.

Moreover, in the Z axis direction, the +Z-side end 73A of the exhaust port 73 may be disposed at the same position as that of the +Z-side end 30A (the +Z-side tip of the fin 32) of the heat sink 30 or may be disposed on the +Z side with respect to the +Z-side end 30A of the heat sink 30.

Moreover, in the Z axis direction, the −Z-side end 73B of the exhaust port 73 may be disposed at the same position as that of the support surface 33 of the heat radiating plate 31, or may be disposed at the +Z side with respect to the support surface 33 of the heat radiating plate 31.

In the above-described embodiment, the first exhaust port 731 provided in the first side plate 521 and the second side plate 522 is set to be long in the Y axis direction. However, similarly to the second exhaust port 732, the first exhaust port 731 may be long in the Z axis direction. In addition, in a case where the first exhaust ports 731 are long in the Z axis direction, the interval between the first exhaust ports 731 adjacent in the Y axis direction may be an integral multiple of the interval between the fins 32 adjacent in the Y axis direction.

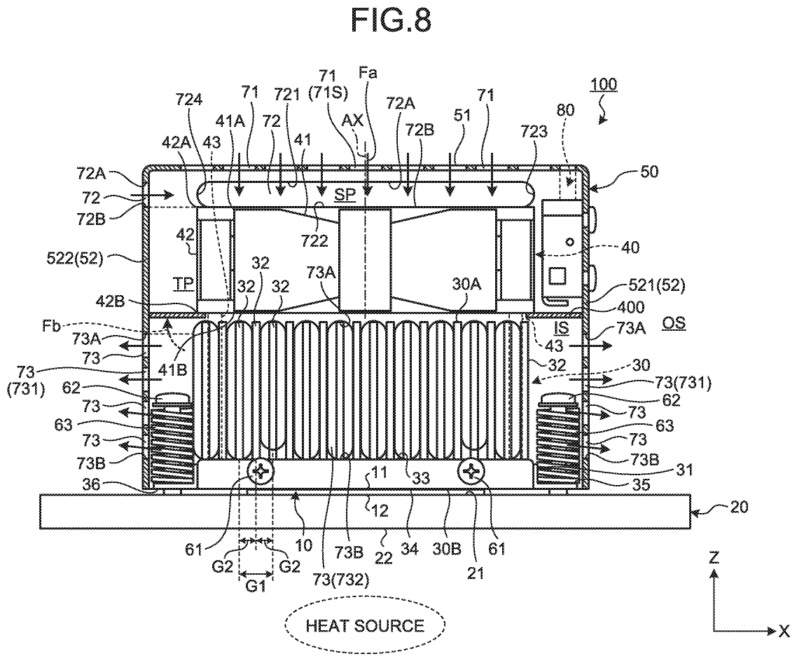

FIG. 8 is a cross-sectional view illustrating the thermoelectric generation device 100 according to the present embodiment. As illustrated in FIG. 8, a baffle 400 may be disposed in at least a portion of the second space TP between the inner surface of the side plate 52, and the fan unit 40 and the heat sink 30. The baffle 400 is an annular member, and divides the second space TP into a +Z-side space and a −Z-side space with respect to the baffle 400. In the example illustrated in FIG. 8, the baffle 400 is disposed so as to connect the end 42B of the fan case 42 of the fan unit 40 and the inner surface of the side plate 52 to each other. The baffle 400 is disposed, and thus, it is possible to sufficiently prevent warmed air flowing out from the heat sink 30 (between the fins 32) from flowing upward through the second space TP as indicated by the arrow Fb.

### REFERENCE SIGNS LIST

10 THERMOELECTRIC GENERATION MODULE
11 END SURFACE
12 END SURFACE
13 P-TYPE THERMOELECTRIC SEMICONDUCTOR ELEMENT
14 N-TYPE THERMOELECTRIC SEMICONDUCTOR ELEMENT
15 ELECTRODE
16 FIRST SUBSTRATE
17 SECOND SUBSTRATE
18 LEAD WIRE
20 HEAT RECEIVING PLATE
21 CONNECTION SURFACE
22 HEAT RECEIVING SURFACE
30 HEAT SINK
30A END
30B END
31 HEAT RADIATING PLATE
32 FIN
33 SUPPORT SURFACE
34 CONNECTION SURFACE
35 FLANGE
36 FLANGE
40 FAN UNIT
41 FAN
41A END
41B END
42 FAN CASE
42A END
42B END
43 SUPPORT MEMBER
50 COVER MEMBER
51 FACING PLATE
52 SIDE PLATE
61 SCREW
62 SCREW
63 COIL SPRING
64 SCREW
71 FIRST INTAKE PORT
72 SECOND INTAKE PORT
72A END
72B END
73 EXHAUST PORT
73A END
73B END
80 CONNECTOR
90 CABLE
100 THERMOELECTRIC GENERATION DEVICE
200 CASSETTE STOVE
300 ELECTRICAL DEVICE
400 BAFFLE
521 FIRST SIDE PLATE
522 SECOND SIDE PLATE
523 THIRD SIDE PLATE
524 FOURTH SIDE PLATE
721 STRAIGHT EDGE
722 STRAIGHT EDGE
723 ARC EDGE
724 ARC EDGE
731 FIRST EXHAUST PORT
732 SECOND EXHAUST PORT
7311 STRAIGHT EDGE
7312 STRAIGHT EDGE
7313 ARC EDGE
7314 ARC EDGE
7321 STRAIGHT EDGE
7322 STRAIGHT EDGE
7323 ARC EDGE
7324 ARC EDGE
AX ROTATION AXIS
IS INTERNAL SPACE
OS EXTERNAL SPACE
SP FIRST SPACE
TP SECOND SPACE

1. A thermoelectric generation device comprising:
a thermoelectric generation module;
a fan which is rotatable about a rotation axis and is disposed on one side of the thermoelectric generation module in a first axis direction parallel to the rotation axis;
a cover member which includes a facing plate which is disposed on one side of the fan in the first axis direction and faces the fan and a side plate which is disposed around the fan from the one side of the fan toward the other side thereof;
a first intake port which is provided in the facing plate;
a second intake port which is provided in the side plate and of which at least a portion is disposed on the one side with respect to the fan in the first axis direction; and
an exhaust port which is provided in the side plate and is disposed on the other side with respect to the fan in the first axis direction.

2. The thermoelectric generation device according to claim 1, wherein
the second intake port faces each of a first space between an inner surface of the facing plate and the fan, and a second space between an inner surface of the side plate and the fan.

3. The thermoelectric generation device according to claim 1, wherein
the second intake port has one side end and the other side end in the first axis direction,
the fan has one side end and the other side end in the first axis direction, and
the other side end of the second intake port is disposed at the same position as that of the one side end of the fan or is disposed on the one side with respect to the one side end of the fan in the first axis direction.

4. The thermoelectric generation device according to claim 1, further comprising:
a heat sink which is disposed between the thermoelectric generation module and the fan in the first axis direction and has a heat radiating plate which is connected to one side end surface of the thermoelectric generation module; and
a heat receiving plate which is connected to the other side end surface of the thermoelectric generation module in the first axis direction.

5. The thermoelectric generation device according to claim 4, wherein
a size of the second intake port is equal to or larger than a size of the heat sink in a direction orthogonal to the rotation axis.

6. The thermoelectric generation device according to claim 5, wherein
the side plate includes a first side plate, and a second side plate which is disposed with a gap with respect to the first side plate in a second axis direction orthogonal to the rotation axis, a third side plate which is disposed between the first side plate and the second side plate and connected to the first side plate and the second side plate, and a fourth side plate which is disposed with a gap with respect to the third side plate in a third axis direction orthogonal to the first axis direction and the second axis direction and connected to the first side plate and the second side plate, and
the second intake port is provided in at least one of the first side plate, the second side plate, the third side plate, and the fourth side plate.

7. The thermoelectric generation device according to claim 4, wherein
the exhaust port has one side end and the other side end in the first axis direction,
the heat sink has one side end and the other side end in the first axis direction, and
the one side end of the exhaust port is disposed on the other side with respect to the one side end of the heat sink in the first axis direction.

8. The thermoelectric generation device according to claim 7, wherein
the heat sink has a fin connected to a support surface of the heat radiating plate,
the one side end of the heat sink includes a tip of the fin, and
the other side end of the exhaust port is disposed on the other side with respect to the support surface of the heat radiating plate in the first axis direction.

9. The thermoelectric generation device according to claim 8, wherein
the exhaust port is long in the first axis direction, and a plurality of the exhaust ports are provided in a direction orthogonal to the rotation axis,
the fin is long in the first axis direction, and a plurality of the fins are provided in the direction orthogonal to the rotation axis, and
a center line of the cover member between the adjacent exhaust ports and a center line of the fin coincide with each other in the direction orthogonal to the rotation axis, and
an interval between the exhaust ports is an integral multiple of an interval between the fins.
